(19) United States
(12) Patent Application Publication
(10) Pub. No.: US 2026/0334069 A1
(43) Pub. Date: Oct. 22, 2026

(54) METHOD FOR MANUFACTURING DOPED ORGANIC SEMICONDUCTOR THIN FILM

(71) Applicant: IUCF-HYU (INDUSTRY-UNIVERSITY COOPERATION FOUNDATION HANYANG UNIVERSITY), Seoul (KR)

(72) Inventors: Jae Young JANG, Seoul (KR); Eui Hyun SUH, Seoul (KR); Taek Seong LEE, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 19/113,688

(22) PCT Filed: Sep. 15, 2023
(86) PCT No.: PCT/KR2023/013948

§ 371 Date: Apr. 30, 2025

(30) Foreign Application Priority Data
Sep. 23, 2022 (KR) 10-2022-0121068

(51) Int. Cl. H10K 71/30; C08K 5/55; C09D 5/24; C09D 7/20; C09D 7/63; C09D 7/80

(52) U.S. Cl. CPC H10K 71/30; C09D 5/24; C09D 7/20; C09D 7/63; C09D 7/80; C08K 5/55

(57) ABSTRACT

The present invention relates to a doped organic semiconductor thin film and a method for producing the same. The method for producing a doped organic semiconductor thin film of the present invention includes dissolving a dopant material in an organic solvent having strong polarity so that doping does not occur in the solution even when mixed with an organic semiconductor material, thereby eliminating the precipitation phenomenon of a composite dopant material in a doping process performed in a solution phase. In addition, an organic semiconductor thin film produced by the method has an effect of improving electrical conductivity by inducing a high level of doping.

### TECHNICAL FIELD

The present invention relates to organic semiconductors, and more particularly, to doped organic semiconductors.

### BACKGROUND ART

In the semiconductor industry, which is called the rice of advanced industries, doping, which intentionally adds impurities to control electrical, optical, and structural characteristics, is an essential technology that is indispensable. Molecular doping, which is similar to doping but in which dopants made of molecules rather than atoms undergo a charge transfer reaction with the semiconductor to form charge carriers, is being widely studied as a technology to improve the electrical conductivity of various organic and inorganic semiconductors, control energy levels, and change absorption characteristics.

Since molecular doping transfers charges through the relative energy level difference between the host semiconductor and the guest dopant, controlling this is a key element of the technology. For example, p-doping requires that the highest occupied molecular orbital (HOMO) level of the semiconductor be higher than the lowest unoccupied molecular orbital (LUMO) level of the dopant. Satisfying this condition can improve the performance of various electronic devices, but the heat that is inevitably generated during the device operation process can diffuse the dopant and hinder the device operation stability. Among various dopant materials, organic dopants, which are materials composed of organic compounds, have the characteristic of easy molecular weight control, and thus, are advantageous materials for suppressing thermal diffusion and improving operating stability.

In particular, organic p-dopants are utilized as key materials for lowering the operating voltage of photovoltaic devices and reducing power consumption due to their excellent operating stability, and their demand is expected to increase further in the future.

In general, when doping an organic semiconductor within a solution, it is known that its solubility drops sharply and it precipitates. Here, the formed doped organic semiconductor precipitates significantly reduce the uniformity of a thin film during the thin film coating process, and act as defects to interfere with the operation of electronic and photovoltaic devices or suppress their performance. In particular, since organic solvents with low polarity generally have low dopant solubility, there is a problem that the organic semiconductor solution should be diluted during the process of being mixed with the dopant solution during the production of an organic semiconductor thin film, which causes difficulties in the process of manufacturing a photovoltaic device where thickness control is important.

### DISCLOSURE

### Technical Problem

The technical problem to be solved by the present invention is to provide a doped organic semiconductor thin film and a method for manufacturing the same.

The technical problems of the present invention are not limited to the technical problems mentioned above, and other technical problems not mentioned will be clearly understood by those skilled in the art from the following description.

### Technical Solution

In order to solve the above problem, one aspect of the present invention provides a method for producing a doped organic semiconductor thin film. The method may comprise producing a composite doping solution comprising an organic compound having a resonance structure having at least one cyano group (C≡N), a Lewis acid, and a first organic solvent; producing an organic semiconductor solution comprising an organic semiconductor material and a second organic solvent; mixing the composite doping solution and the organic semiconductor solution to produce a mixed solution; and coating the mixed solution on a substrate to form a thin film, and evaporating the organic solvent in the thin film.

The first organic solvent may have a larger dielectric constant value than the second organic solvent.

The first organic solvent may be an organic solvent having a strong polarity compared to the second organic solvent, and may have a dielectric constant value of 16 to 50 at room temperature. For example, the first organic solvent may include at least one selected from acetone, acetonitrile (ACN), dimethylformamide (DMF), and combinations thereof, but is not limited thereto.

The second organic solvent may be an organic solvent having a weak polarity compared to the first organic solvent, and may have a dielectric constant value of 1 to 15 at room temperature. For example, the second organic solvent may include at least one selected from dichlorobenzene (DCB), ethyl acetate (EtOAc), and combinations thereof, but is not limited thereto.

In the mixed solution, bonding of the organic compound and the Lewis acid may be suppressed. A composite dopant compound formed by bonding the organic compound and the Lewis acid in the thin film from which the organic solvent has evaporated may dope the organic semiconductor material.

The bonding may form a Lewis pair formed by the cyano group (C≡N) of the organic compound and the Lewis acid.

The organic semiconductor material may contain an alkyl side chain in its molecular structure.

In order to solve the above problem, another aspect of the present invention provides a doped organic semiconductor thin film. The doped organic semiconductor thin film comprises a composite dopant compound in which an organic compound having a resonance structure having at least one cyano group (C≡N) and a Lewis acid are combined and an organic semiconductor material doped with the composite dopant compound.

The combination of the organic compound and the Lewis acid forms a Lewis pair between the cyano group (C≡N) of the organic compound and the Lewis acid.

While the thin film is formed using a composite doping solution containing the organic compound, the Lewis acid, and an organic solvent, the combination may be formed after the organic solvent evaporates.

The organic solvent may have a dielectric constant value of 16 to 50 at room temperature.

The organic solvent may be at least one selected from, but is not limited to, acetone, acetonitrile (ACN), dimethylformamide (DMF), and combinations thereof.

The organic semiconductor material may contain an alkyl side chain in its molecular structure.

### Advantageous Effects

The method for manufacturing a doped organic semiconductor thin film of the present invention comprises dissolving a dopant material in an organic solvent having strong polarity so that doping does not occur in the solution even when mixed with an organic semiconductor material, thereby eliminating the precipitation phenomenon of a composite dopant material in a doping process performed in a solution phase. In addition, the organic semiconductor thin film manufactured by this method has improved electrical conductivity by having a high level of doping.

### DESCRIPTION OF DRAWINGS

FIG. 1 is a flow chart of a method for manufacturing a doped organic semiconductor thin film according to an embodiment of the present invention.

FIG. 2 shows (a) a schematic diagram showing a bond formed between an organic semiconductor compound having a resonance structure and a Lewis acid according to the polarity of a solvent, and (b) a graph showing the LUMO level of the organic material before/after the Lewis acid is bonded according to an Example of the present invention.

FIG. 3 shows photographs confirming whether or not the organic semiconductor material is doped according to the type of organic solvent used in an Example of the present invention.

FIG. 4 shows a graph (left) showing the UV-vis-NIR absorbance of an organic semiconductor compound solution doped with a dopant compound in an Example of the present invention, and a graph (right) showing the UV-vis-NIR absorbance after 7 days.

FIG. 5 shows digital camera photographs (left) and a graph (right) showing the UV-vis-NIR absorbance of an organic semiconductor compound thin film doped with a dopant ratio of 20 mol % in an Example of the present invention.

FIG. 6 shows digital camera photographs (left) and a graph (right) showing the UV-vis-NIR absorbance of an organic semiconductor compound thin film doped with a dopant ratio of 50 mol % in an Example of the present invention.

FIG. 7 shows digital photographs of the surface of a thin film taken immediately after formation of the thin film (left) and 30 seconds after formation of the thin film (right) when acetonitrile (ACN) was used as a dopant solvent in an Example of the present invention.

FIG. 8 shows a digital camera photograph (left) of a thin film when the PCDTFBT organic semiconductor material is doped at a molar ratio of 50%, a UV-vis-NIR absorbance graph thereof (middle), and a UV-vis-NIR absorbance graph (right) of a PDPP3T organic semiconductor film doped in the same manner according to an Example of the present invention.

FIG. 9 shows a UV-vis-NIR absorbance graph (left) of organic semiconductor thin films using doping solutions in which doping materials are dissolved in ACN according to Examples of the present invention, and a graph (right) showing electrical conductivities of doped organic semiconductor thin films prepared by dissolving the doping materials in ACN and DMF solvents.

FIG. 10 shows digital photographs of organic semiconductor solutions using various organic solvents according to an Example of the present invention and thin films manufactured using the organic semiconductor solutions.

### MODES OF THE INVENTION

The present invention can be modified in various ways and can take various forms, and specific embodiments are illustrated in the drawings and described in detail in the text. However, this is not intended to limit the present invention to a specific disclosed form, and it should be understood that it includes all modifications, equivalents, or substitutes included in the spirit and technical scope of the present invention. Similar reference numerals are used for similar components in describing each drawing.

Unless otherwise defined, all terms used herein, including technical or scientific terms, have the same meaning as commonly understood by a person of ordinary skill in the art to which the present invention belongs. Terms defined in commonly used dictionaries should be interpreted as having a meaning consistent with the meaning they have in the context of the relevant technology, and shall not be interpreted in an ideal or excessively formal sense unless explicitly defined in this application.

Throughout this specification, when a part is said to “include” a component, this does not mean excluding other components, but rather that other components can be included, unless otherwise specifically stated.

The terms “about,” “substantially,” etc., used throughout this specification are used in the sense that they are at or near the numerical value when a material tolerance is presented in the sense stated, and are used to prevent unscrupulous infringers from unfairly exploiting the disclosure in which exact or absolute values are stated to aid understanding of this specification.

### Method for Manufacturing Doped Organic Semiconductor Thin Film

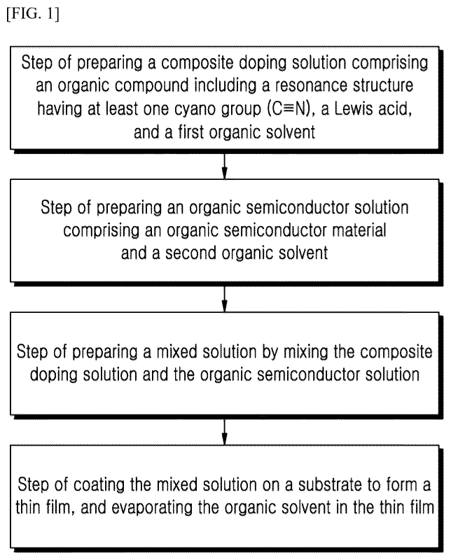

FIG. 1 is a flow chart of a method for manufacturing a doped organic semiconductor thin film according to an embodiment of the present invention.

Referring to FIG. 1, a method for manufacturing a doped organic semiconductor thin film of the present invention is provided. First, an organic compound including a resonance structure having at least one cyano group (C≡N) and a first organic solvent may be mixed to obtain a first mixed solution. Separately, a Lewis acid that binds to the cyano group (C≡N) and the first organic solvent may be mixed to obtain a second mixed solution. The first mixed solution and the second mixed solution may be mixed at a certain ratio to prepare a composite doping solution.

The organic compound may include an organic resonance structure having at least one, for example, two or more cyano groups (C≡N) in the molecule. The above cyano group (C≡N) is an electron withdrawing group (EWG) that withdraws electrons from the resonance structure and may refer to a Lewis base donating electron to the Lewis acid. The organic compound may form a Lewis pair by combining with the Lewis acid material detailed below and may form a composite dopant compound having strong doping properties in an organic semiconductor thin film, or may be used as an organic dopant material by itself.

The above organic compound can be represented by the following Chemical Formula 1.

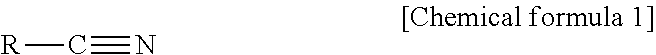

The above R is the organic resonance structure, and may include at least one selected from, for example, an aromatic ring, a quinonoid ring, a double bond, a triple bond, allene, butadiene, polyene, oxocarbon, pseudooxocarbon, radialene, analogs thereof, and derivatives thereof.

Specifically, the above R may include at least one selected from compounds represented by the following Chemical Formulas 2 to 24, but is not limited thereto.

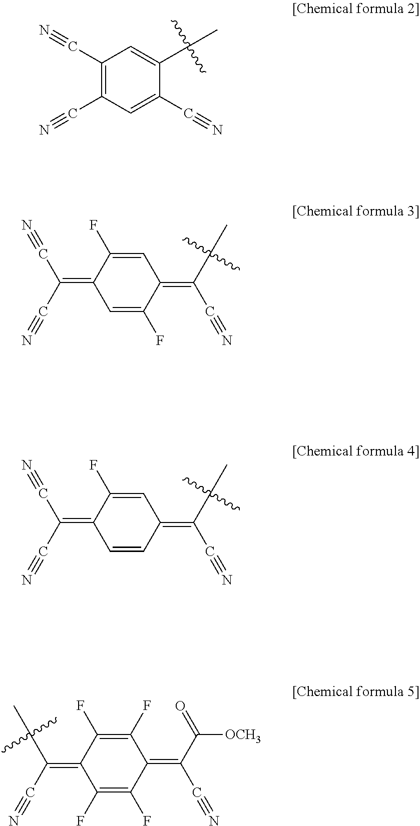 [SMILES: *c1cc(C#N)c(C#N)cc1C#N ; */C(C#N)=c1\cc(F)c(=C(C#N)C#N)cc1F ; */C(C#N)=c1/ccc(=C(C#N)C#N)c(F)c1 ; *C(C#N)=c1c(F)c(F)c(=C(C#N)C(=O)OC)c(F)c1F]

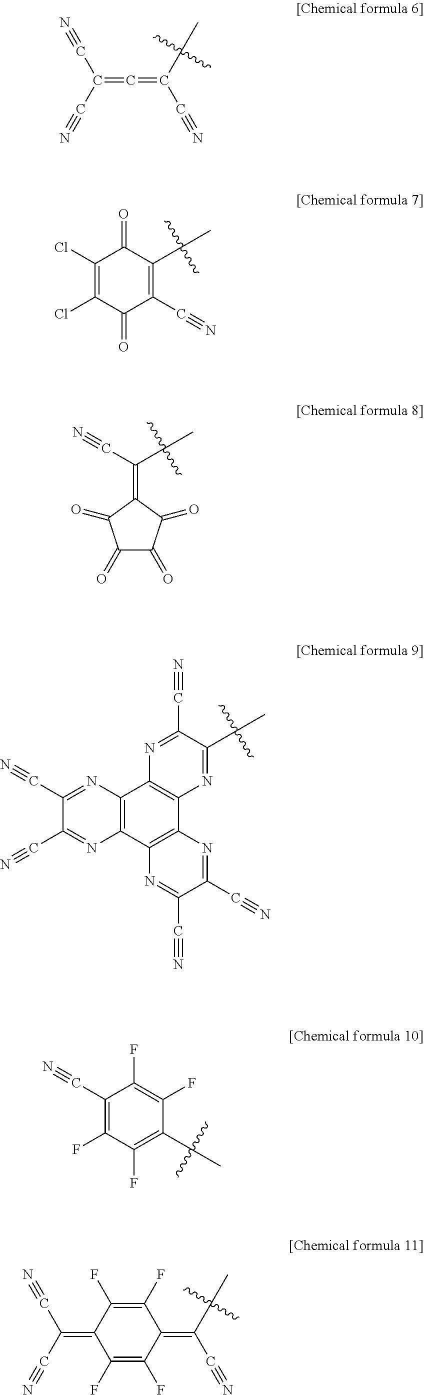 [SMILES: *C(=C=C(C#N)C#N)C#N ; *C1=C(C#N)C(=O)C(Cl)=C(Cl)C1=O ; *C(C#N)=C1C(=O)C(=O)C(=O)C1=O ; *c1nc2c(nc1C#N)c1nc(C#N)c(C#N)nc1c1nc(C#N)c(C#N)nc21 ; *c1c(F)c(F)c(C#N)c(F)c1F ; *C(C#N)=c1c(F)c(F)c(=C(C#N)C#N)c(F)c1F]

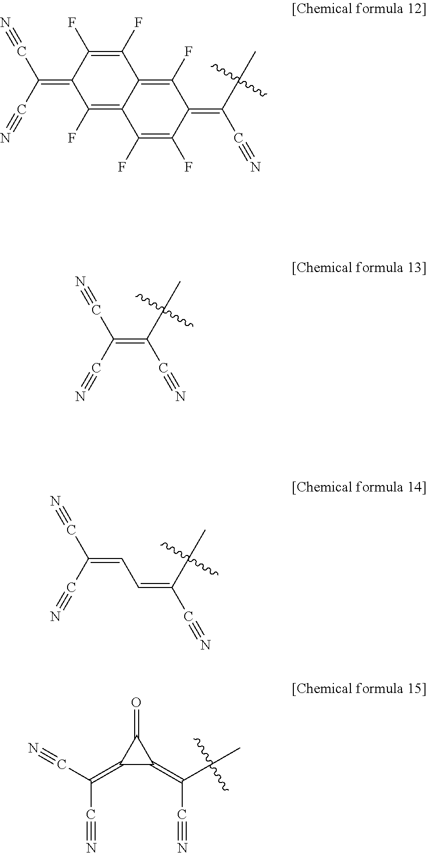 [SMILES: */C(C#N)=c1/c(F)c(F)c2c(F)c(=C(C#N)C#N)c(F)c(F)c2c1F ; *C(C#N)=C(C#N)C#N ; */C(C#N)=C\C=C(C#N)C#N ; */C(C#N)=c1\c(=O)c1=C(C#N)C#N]

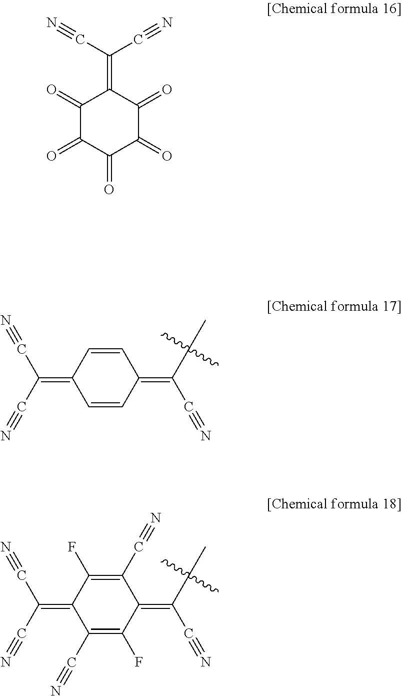 [SMILES: N#CC(C#N)=C1C(=O)C(=O)C(=O)C(=O)C1=O ; *C(C#N)=c1ccc(=C(C#N)C#N)cc1 ; */C(C#N)=c1/c(F)c(C#N)c(=C(C#N)C#N)c(F)c1C#N]

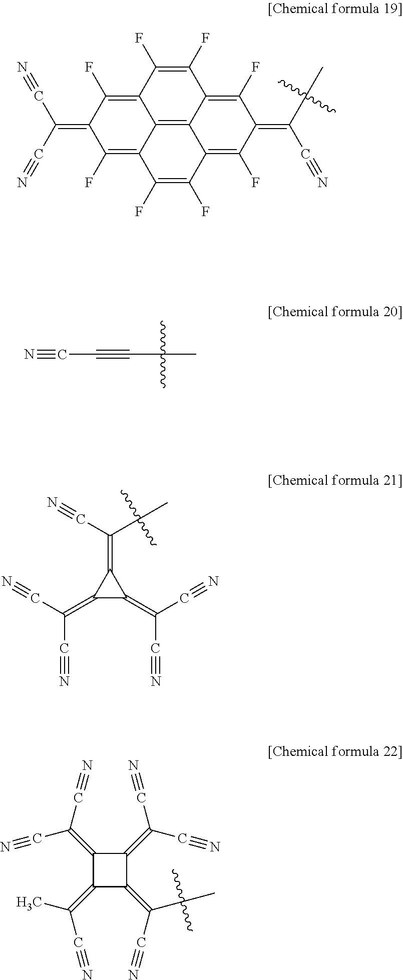 [SMILES: *C(C#N)=c1c(F)c2c(F)c(F)c3c(F)c(=C(C#N)C#N)c(F)c4c(F)c(F)c(c1F)c2c34 ; *C#CC#N ; *C(C#N)=C1C(=C(C#N)C#N)C1=C(C#N)C#N ; */C(C#N)=C1\C(=C(C#N)C#N)C(=C(C#N)C#N)\C1=C(/C)C#N]

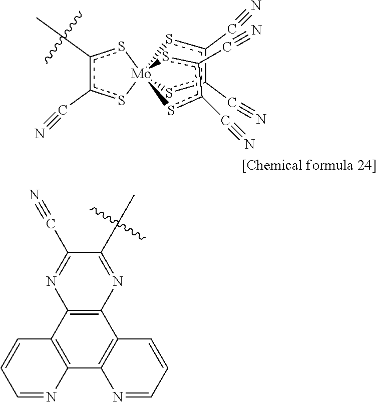

The above organic compound may be a p-type or n-type organic dopant, for example, a p-type organic dopant, and may include at least one selected from, for example, tetracyanoethylene (TCNE), 7,7,8,8-tetracyanoquinodimethane (TCNQ), 2,3,5,6-tetrafluoro-tetracyanoquinodimethane (FTCNQ), 2,5-difluoro-7,7,8,8-tetracyanoquinodimethane (F2TCNQ), 2,3-dichloro-5,6-dicyano-1,4-benzoquinone (DDQ), 2,3,5,6-tetrafluoro-tetracyanoquinodimethane (F4TCNQ), analogs thereof, and derivatives thereof. In one specific example, the organic compound may be 2,3,5,6-tetrafluoro-tetracyanoquinodimethane (F4TCNQ), but is not limited thereto.

The organic compound can be dissolved in the first organic solvent detailed below to prepare the first doping solution. The concentration of the first doping solution may be 0.5 to 30 mg/mL, specifically 1 to 20 mg/mL, for example 2 to 10 mg/mL, but is not limited thereto.

The Lewis acid (LA) can bond with the cyano group present in a molecule of the organic compound in the organic semiconductor thin film detailed below to form the composite dopant compound that dopes the organic semiconductor material. The above bond is a bond in which a cyano group (C≡N) acting as a Lewis base in the organic compound and the Lewis acid form a Lewis pair, and may include, for example, a covalent bond, a coordinate bond, or a secondary bond including these, for example, a van der Waals bond, a dipole-dipole bond, etc. In one specific example, the Lewis acid may include, but is not limited to, at least one selected from tris(pentafluorophenyl)borane (BCF), bis(pentafluorophenyl)zinc (Zn(C₆F₂)₂), boron tribromide (BBr₃), molybdenum chloride (MoCl₅), and combinations thereof.

The second doping solution can be prepared by dissolving the Lewis acid material in the first organic solvent detailed below. The concentration of the second doping solution can be 20 to 200 mg/mL, specifically 50 to 150 mg/mL, for example 80 to 120 mg/mL, but is not limited thereto.

The first organic solvent can be a solvent having Lewis basicity or a polar organic solvent having a high dielectric constant value. Specifically, the first organic solvent can have a dielectric constant value greater than that of a second organic solvent described below. Specifically, the first organic solvent can have a dielectric constant value of 16 to 50, more specifically 18 to 45, and in one specific example 20 to 40 at room temperature. In the mixed doping solution, the first organic solvent having strong polarity may have the effect of suppressing the formation of the composite dopant material formed by a bond between the Lewis acid material and the organic compound forming a Lewis pair. For example, the first organic solvent may be at least one selected from acetone, acetonitrile (ACN), dimethylformamide (DMF), and combinations thereof.

The above mixed solution may be a mixture in which the organic compound material included in the first mixed solution and the Lewis acid material included in the second mixed solution are mixed in a molar ratio of 1:1 to 1:10, specifically 1:1 to 1:7, more specifically 1:1 to 1:5, and in one specific example 1:1 to 1:4, but is not limited thereto.

Separately, an organic semiconductor solution in which an organic semiconductor material is dissolved in a second organic solvent may be prepared.

The second organic solvent may be a polar organic solvent capable of dissolving the organic semiconductor material and having a low dielectric constant value, specifically having a dielectric constant value of 1 to 15, more specifically, 3 to 12, and in one specific example, 5 to 10 at room temperature.

The organic semiconductor material may be an organic material that can be doped with the above-described composite dopant compound, and specifically, may be an organic semiconductor material having an alkyl side chain in its molecular structure. The organic semiconductor material having an alkyl side chain in its molecular structure may be a material that is highly likely to aggregate and generate a precipitate in a solution during the doping process. The above organic semiconductor material is, for example, PDPP3T(Poly{2,2′-[(2,5-bis(2-hexyldecyl)-3,6-dioxo-2,3,5,6-tetrahydropyrrolo[3,4-c]pyrrole-1,4-diyl)dithiophene]-5,5′-diyl-alt-thiophen-2,5-diyl}), PCDTFBT(Poly[(5-fluoro-2,1,3-benzothiadiazole-4,7-diyl)(4,4-dihexadecyl-4H-cyclopenta[2,1-b;3,4-b′]dithiophene-2,6-diyl)(6-fluoro-2,1,3-benzothiadiazole-4,7-diyl)(4,4-dihexadecyl-4H-cyclopenta[2,1-b;3,4-b′]dithiophene-2,6-diyl)), P3HT (Poly(3-hexylthiophene-2,5-diyl)), and combinations thereof, but are not limited thereto.

The concentration of the above organic semiconductor solution may be, but is not limited to, 1 to 50 mg/mL, specifically 3 to 40 mg/mL, more specifically 5 to 30 mg/mL, and for example 7 to 20 mg/mL.

Next, a step of preparing a mixed solution by mixing the composite doping solution and the organic semiconductor solution may be performed.

The mixed solution is a mixture of the composite doping solution and the organic semiconductor solution, and the dopant ratio of the composite doping solution may be 5 to 70 mol %, specifically 10 to 60 mol %, and in one example 20 to 50 mol %, relative to the total mole number of the organic semiconductor material and the composite dopant material.

The mixed solution contains the organic compound material, the Lewis acid material, and the organic semiconductor material in an organic solvent. In the mixed solution, the first organic solvent having strong polarity may have already formed a bond by reacting with the Lewis acid, thereby inhibiting the reaction between the cyano group of the organic compound and the Lewis acid, i.e., inhibiting the formation of a Lewis pair, thereby suppressing the formation of a composite dopant compound. In the mixed solution in which the formation of a composite dopant compound is suppressed, the Lewis acid and the cyano group can be bonded only after the solvent has evaporated in the manufacturing process of a thin film detailed below, and a p-type composite dopant compound having strong oxidizing properties can be formed, thereby enabling a very high level of doping. Therefore, the mixed solution may be referred to as a doping solution having a potential doping ability that induces doping after the thin film is formed without a reaction occurring in the solution. If an organic solvent having low polarity, such as the second organic solvent, is used as the first organic solvent, the cyano group of the organic compound and the Lewis acid may react in the step of preparing the mixed solution to form a composite dopant compound, such as F4TCNQ:BCF, P3HT, and then precipitate, which may result in the formation of a precipitate in the solution. As a result, when the thin film preparation process described below is performed, an uneven and bumpy organic semiconductor thin film may be formed, which may be undesirable.

Thereafter, a step of coating the above-mentioned mixed solution on a substrate to form a thin film, and evaporating the organic solvent in the thin film can be performed.

The method of forming the thin film can be a method of forming a thin film based on a solution generally known in the art, non-limiting examples thereof include dip coating, bar coating, spray coating, brush coating, spin coating, slot-die coating, solution casting, gravure coating, roll coating, dropping, printing, etc.

The organic solvent may include at least one selected from the above-mentioned first organic solvent and the second organic solvent, and evaporates during the process of forming the thin film, specifically, most of the organic solvent, for example, all of the organic solvent, so that no organic solvent may remain in the thin film. When the organic solvent evaporates, the cyano group of the organic compound in the organic semiconductor thin film may react and combine with the Lewis acid to form a p-type composite dopant compound having strong oxidizing properties, and the composite dopant compound may be a doping material having strong oxidizing properties and can dope the organic semiconductor material to a high level.

The composite dopant compound is formed by a bond between the above-described organic compound and a Lewis acid, and may include at least one Lewis pair, specifically a bond between the cyano group and the Lewis acid, within the molecular structure.

The manufactured thin film may have a thickness of nanometers, for example, a thickness of tens to hundreds of nanometers.

Hereinafter, in order to explain the present invention more specifically, a preferred experimental example according to the present invention will be described in more detail with reference to the attached drawings. However, the present invention is not limited to the embodiments described herein and may be embodied in other forms.

### Experimental Example: Synthesis of Mixed Doping Solution F4TCNQ:BCF

A first doping solution was prepared by dissolving F4TCNQ, an organic compound having cyano groups, in a first organic solvent at 2 to 10 mg/mL. The material used as the first organic solvent was acetone, acetonitrile (ACN), or dimethylformamide (DMF). Separately, tris(pentafluorophenyl)borane (BCF), a Lewis acid material, was dissolved in each of the first organic solvent at 100 mg/mL to prepare a second doping solution. Each doping solution was heated to 90° C. to prevent precipitation and completely dissolve.

The first mixed solution and the second mixed solution were mixed so that the organic compound having cyano groups and the Lewis acid material had a molar ratio of 1:2 to 1:4 to prepare composite doping solutions. If the color of the composite doping solution changes from before mixing, it is confirmed that a reaction has occurred between the two materials. All of the above processes were performed in a nitrogen atmosphere.

### Example: Formation of an Organic Semiconductor Thin Film Doped with a Mixed Doping Solution

An organic semiconductor solution was prepared by dissolving an organic semiconductor material such as PDPP3T(Poly{2,2′-[(2,5-bis(2-hexyldecyl)-3,6-dioxo-2,3,5,6-tetrahydropyrrolo[3,4-c]pyrrole-1,4-diyl)dithiophene]-5,5′-diyl-alt-thiophen-2,5-diyl}), PCDTFBT(Poly[(5-fluoro-2,1,3-benzothiadiazole-4,7-diyl)(4,4-dihexadecyl-4H-cyclopenta[2,1-b;3,4-b′]dithiophene-2,6-diyl)(6-fluoro-2,1,3-benzothiadiazole-4,7-diyl)(4,4-dihexadecyl-4H-cyclopenta[2,1-b;3,4-b′]dithiophene-2,6-diyl)) or P3HT(Poly(3-hexylthiophene-2,5-diyl)) in dichlorobenzene (DCB), a second organic solvent, at a concentration of 10 mg/mL. The organic semiconductor solution and the mixed doping solution produced in Experimental Example were mixed so that F4TCNQ was 20 to 50 mol % based on the total mole number of the organic semiconductor material and the composite dopant material to prepare a mixed solution, and the mixed solution was applied onto a washed glass substrate and spin-coated at 1000 rpm for 60 seconds to form a doped organic semiconductor thin film with a thickness of several tens of nanometers. The presence of doping was confirmed based on whether the mixed doping solution precipitated.

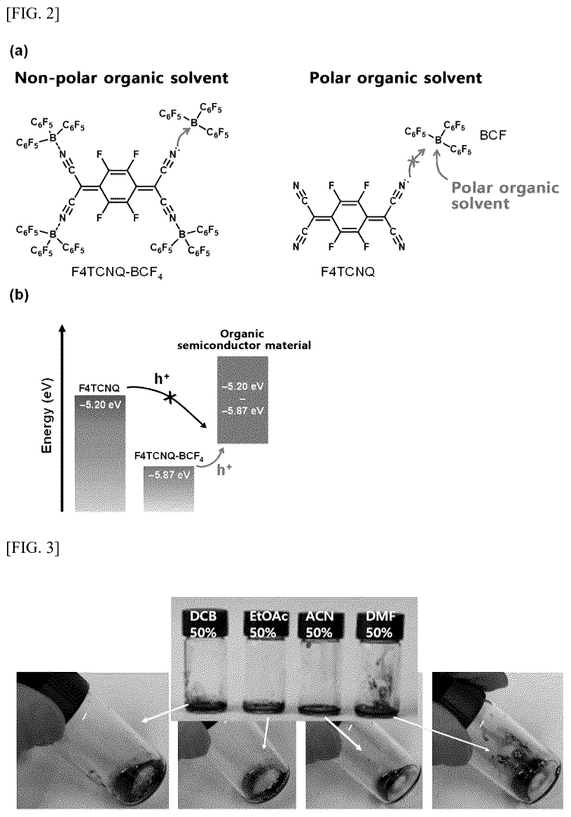

FIG. 2 shows (a) a schematic diagram showing a bond formed between an organic semiconductor compound having a resonance structure and a Lewis acid according to the polarity of a solvent, and (b) a graph showing the LUMO level of the organic material before/after the Lewis acid is bonded according to an Example of the present invention.

Referring to FIG. 2, the organic compound (F4TCNQ) having cyano groups with the resonance structure of the present invention can form a composite dopant compound (F4TCNQ-BCF₄) by forming a bond between the organic semiconductor compound and a Lewis acid (BCF) in a nonpolar organic solvent. On the other hand, in a polar organic solvent, the organic compound (F4TCNQ) does not form a bond with the Lewis acid (BCF), but instead, a material used as a polar organic solvent can react with the Lewis acid (BCF) to form a bond, so that the formation of the composite compound can be suppressed. Although the organic compound (F4TCNQ) alone has a high LUMO level, when formed into the composite dopant compound (F4TCNQ-BCF₄), the LUMO level is sufficiently lowered to enable the movement of holes to an organic semiconductor material.

TABLE 1

| Organic solvent | Dielectric constant |
|---|---|
| Ethyl acetate (EtOAc) | 6.02 |
| Dichlorobenzene (DCB) | 9.93 |
| Acetone | 20.7 |
| Dimethylformamide (DMF) | 36.71 |
| Acetonitrile (ACN) | 37.5 |

Table 1 shows the dielectric constant of an organic solvent according to an Example of the present invention. FIG. 3 shows photographs confirming whether or not the organic semiconductor material is doped according to the type of organic solvent used in an Example of the present invention.

Referring to Table 1 and FIG. 3, when the organic semiconductor material PDPP3T is dissolved in dichlorobenzene (DCB), and F4TCNQ as an organic compound having cyanide groups is dissolved in dichlorobenzene (DCB) or ethyl acetate (EtOAc), and then the organic semiconductor (PDPP3T) solution and the organic compound solution are mixed at 50 mol %, it can be seen that the organic semiconductor (PDPP3T) is doped and precipitates in the solution. At this time, the dielectric constants of ethyl acetate (EtOAc) and dichlorobenzene (DCB) as organic solvents are 6.02 and 9.93, respectively, and are solvents with low polarity. Accordingly, it can be seen that when organic semiconductor materials and organic compounds are dissolved using ethyl acetate (EtOAc) or dichlorobenzene (DCB), which are organic solvents with low polarity, doping is performed within the solution. On the other hand, when the organic compound material having the cyanide group is dissolved in acetonitrile (ACN) or dimethylformamide (DMF) with strong polarity and mixed with the organic semiconductor solution in which the solvent is dichlorobenzene (DCB) with weak polarity, it can be confirmed that the organic semiconductor material PDPP3T is not doped and no precipitate is formed. Here, the dielectric constants of acetonitrile (ACN) and dimethylformamide (DMF) as organic solvents are 37.5 and 36.7, respectively, which are solvents with strong polarity. Therefore, when an organic compound having cyanide groups is dissolved in an organic solvent having strong polarity, an organic semiconductor material is dissolved in an organic solvent having weak polarity, and these are mixed to form a mixed solution, it can be confirmed that the Lewis acid reacts with the strong polar solvent instead of the cyanide group (C≡N), thereby suppressing doping of the organic semiconductor material, and thus no organic semiconductor precipitate is formed.

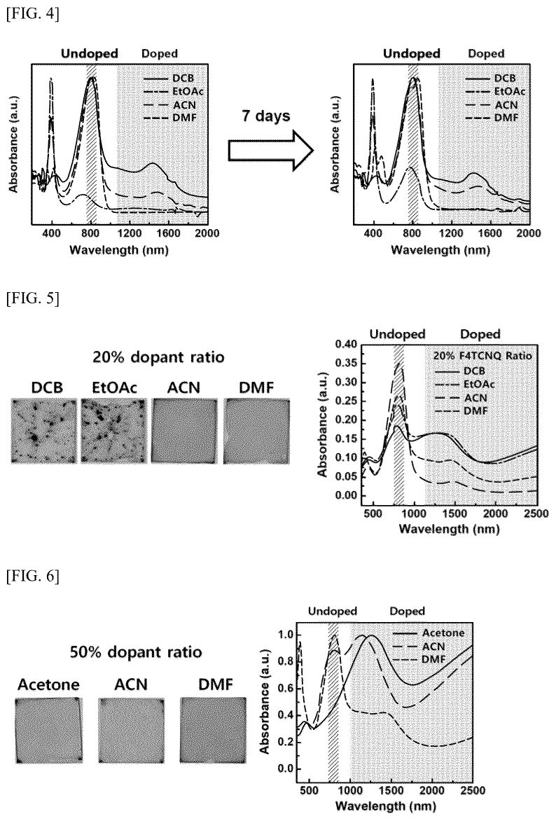

FIG. 4 shows a graph (left) showing the UV-vis-NIR absorbance of an organic semiconductor compound solution doped with a dopant compound in an Example of the present invention, and a graph (right) showing the UV-vis-NIR absorbance after 7 days.

Referring to FIG. 4, when doping an organic semiconductor with a dopant compound using various organic solvents, it can be seen that excellent stability is exhibited since no significant change is observed in the absorbance characteristics of the solution even after a week.

FIG. 5 shows digital camera photographs (left) and a graph (right) showing the UV-vis-NIR absorbance of an organic semiconductor compound thin film doped with a dopant ratio of 20 mol % in an Example of the present invention.

Referring to FIG. 5, dichlorobenzene (DCB), ethyl acetate (EtOAc), acetonitrile (ACN), or dimethylformamide (DMF) as a dopant solvent were mixed with F4TCNQ and BCF to use as a doping solution, and PDPP3T dissolved in dichlorobenzene (DCB) was used as an organic semiconductor solution, and the above solutions were mixed at a dopant ratio of 20 mol % to produce a mixed solution, and this mixed solution was spin-coated to form an organic semiconductor thin film. As a result, when DCB and EtOAc, which are organic solvents with low polarity, were used as dopant solvents, the organic semiconductor thin film was not uniform and sediments remained on the surface thereof, but when ACN and DMF, which are organic solvents with strong polarity, were used as dopant solvents, it was confirmed that no sediments were found on the surface of the thin film and the thin film was formed evenly.

FIG. 6 shows digital camera photographs (left) and a graph (right) showing the UV-vis-NIR absorbance of an organic semiconductor compound thin film doped with a dopant ratio of 50 mol % in an Example of the present invention.

Referring to FIG. 6, acetone, acetonitrile (ACN), or dimethylformamide (DMF) was mixed with F4TCNQ and BCF as a dopant solvent to form an organic compound solution, and PDPP3T dissolved in dichlorobenzene (DCB) was used as an organic semiconductor solution, and the above solutions were mixed with a dopant ratio of 50 mol % to prepare a mixed solution, and the mixed solution was spin-coated to form an organic semiconductor thin film. As a result, it can be seen that when an organic solvent having a relatively strong polarity was used as a dopant solvent, doping was performed well and thus no precipitate was formed, thereby forming a smooth thin film. In addition, the UV-vis-NIR absorbance measurement results show that the neutral PDPP3T peak appearing near 800 nm decreases rapidly while the polaron peak increases rapidly, confirming that the doping was performed well.

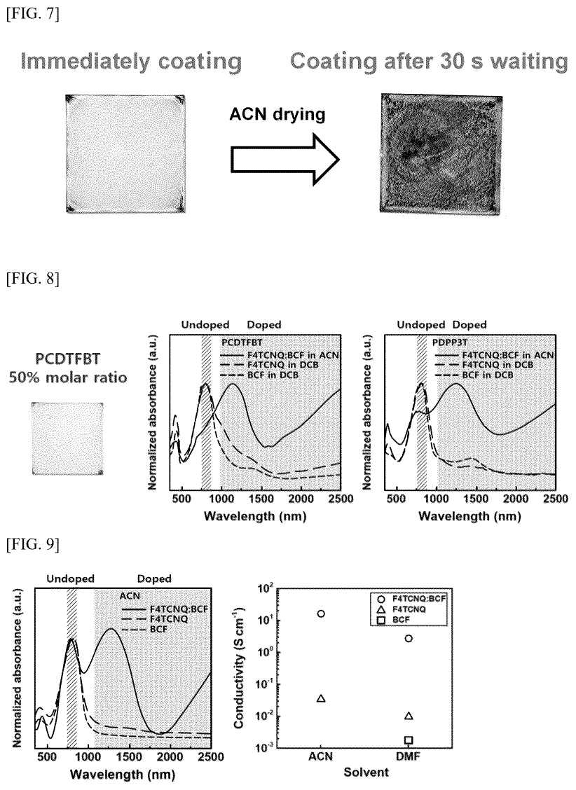

FIG. 7 shows a digital photograph of the surface of a thin film, in which a mixed doping solution was dropped on a substrate and an organic semiconductor thin film was coated immediately (left) and a digital photograph of the surface of a thin film, in which a mixed doping solution was dropped on a substrate and an organic semiconductor thin film was coated 30 seconds later (right) in an Example of the present invention.

Referring to FIG. 7, in order to confirm the role of the dopant solvent, a mixed doping solution using ACN as a dopant solvent was dropped on a substrate, maintained for 30 seconds, and then an organic semiconductor thin film was spin-coated. As a result, it can be confirmed that a non-uniform thin film is formed. This is because ACN, which suppress the reaction between F4TCNQ and BCF but has a low boiling point, evaporates rapidly, causing doping, resulting in the formation of a non-uniform thin film. This result may mean that the Lewis acid binds to the dopant solvent for potential doping instead of the CN group, suppressing the formation of a dopant with strong oxidizing properties, but the solvent evaporates to form a bond between the Lewis acid and the CN group, which exhibits strong oxidizing properties and then reacts with the organic semiconductor.

FIG. 8 shows a digital camera photograph (left) of a thin film when the PCDTFBT organic semiconductor material is doped at a molar ratio of 50%, a UV-vis-NIR absorbance graph thereof (middle), and a UV-vis-NIR absorbance graph (right) of a PDPP3T organic semiconductor film doped in the same manner according to an Example of the present invention.

Referring to FIG. 8, when the dopant solution (F4TCNQ:BCF solution dissolved in ACN) of the present invention is applied to the conjugated polymer PCDTFBT for doping, it can be confirmed that the strongly polar solvent ACN forms a uniform thin film without forming a precipitate in the solution state, and a very high level of doping occurs. Therefore, it can be seen that when a solvent with strong polarity and Lewis basicity is used, the formation of the dopant is suppressed in the solution, but after the thin film is formed, the solvent evaporates to form a composite dopant with strong oxidizing properties, and then the organic semiconductor is doped.

FIG. 9 shows a UV-vis-NIR absorbance graph (left) of organic semiconductor thin films using doping solutions in which doping materials are dissolved in ACN according to Examples of the present invention, and a graph (right) showing electrical conductivities of doped organic semiconductor thin films prepared by dissolving the doping materials in ACN and DMF solvents.

Referring to FIG. 9, each of F4TCNQ:BCF, F4TCNQ, and BCF as a doping material was dissolved in ACN, a strong polar organic solvent, to prepare doping solutions, and the electrical conductivities of the organic semiconductor thin films doped with these doping solutions were measured. The electrical conductivities of the organic semiconductor thin films were measured as 16.51 S/cm (F4TCNQ:BCF) and 0.036 S/cm (F4TCNQ), and, in the case of BCF, electrical conductivity could not be measured because doping did not occur. In addition, each of F4TCNQ:BCF, F4TCNQ, and BCF as a doping material was dissolved in DMF, a weak polar organic solvent, to prepare doping solutions, and the electrical conductivities of the organic semiconductor thin films doped with these were measured. The electrical conductivities of the organic semiconductor thin films were measured as 2.77 S/cm (F4TCNQ:BCF), 0.010 S/cm (F4TCNQ), and 0.0018 S/cm (BCF). As described above, when F4TCNQ:BCF is used as a doping material, the doping ability can be improved by using ACN or DMF as a dopant solvent, and in particular, when ACN, a polar organic solvent, is used, the electrical conductivity of the organic semiconductor thin film can be improved through better doping.

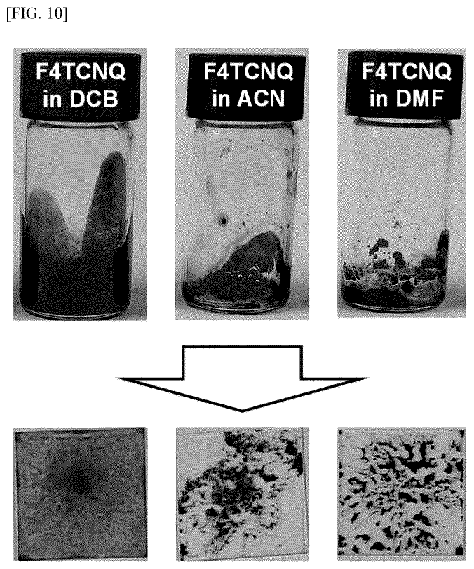

FIG. 10 shows digital photographs of an organic semiconductor solution using various organic solvents according to an Example of the present invention and thin films manufactured using the organic semiconductor solution.

Referring to FIG. 10, an organic semiconductor thin film was manufactured using a solution in which a doping solution of F4TCNQ dissolved in DCB, ACN, or DMF was mixed at a molar ratio of 20% in an organic semiconductor solution in which an organic semiconductor P3HT was dissolved in DCB. As a result, it can be confirmed that when F4TCNQ, an organic compound having a cyanide group, was dissolved in ACN or DMF, which has strong polarity, and mixed with the organic semiconductor P3HT solution, a precipitation occurred due to a strong reaction between F4TCNQ and P3HT. The above results are different from the results in which the organic semiconductor material of the present invention is doped with a composite dopant compound, and it can be seen that when an organic compound having a cyano group sufficiently acts as a p-type dopant, a reaction between the p-dopant and P3HT occurs when a polar organic solvent is used, resulting in doping.

As described above, the method for manufacturing a doped organic semiconductor thin film of the present invention enables a solution-phase doping process for an organic semiconductor material having an alkyl side chain, which is difficult to dope due to a high possibility of agglomeration and formation of precipitates in the solution during the doping process, and therefore can be applied to a wide range of fields, including light-emitting devices such as organic light-emitting diodes and quantum dot light-emitting diodes, photovoltaic devices such as perovskite solar cells and organic solar cells, transistors, thermoelectric devices, electrochemical devices, spin devices, sensors, catalysts, and electrodes.

While the exemplary embodiments of the present invention have been described above, those of ordinary skill in the art should understood that various changes, substitutions and alterations may be made herein without departing from the spirit and scope of the present invention as defined by the following claims.

1. A method for producing a doped organic semiconductor thin film, comprising:
producing a composite doping solution comprising an organic compound having a resonance structure having at least one cyano group (C≡N), a Lewis acid, and a first organic solvent;
producing an organic semiconductor solution comprising an organic semiconductor material and a second organic solvent;
mixing the composite doping solution and the organic semiconductor solution to produce a mixed solution; and
coating the mixed solution on a substrate to form a thin film, and evaporating the organic solvent in the thin film.

2. The method of claim 1, wherein the first organic solvent has a larger dielectric constant value than the second organic solvent.

3. The method of claim 2, wherein the first organic solvent has a dielectric constant value of 16 to 50 at room temperature.

4. The method of claim 2, wherein the second organic solvent has a dielectric constant value of 1 to 15 at room temperature.

5. The method of claim 3, wherein the first organic solvent comprises at least one selected from acetone, acetonitrile (ACN), dimethylformamide (DMF), and combinations thereof.

6. The method of claim 4, wherein the second organic solvent comprises at least one selected from dichlorobenzene (DCB), ethyl acetate (EtOAc), and combinations thereof.

7. The method of claim 1, wherein bonding of the organic compound and the Lewis acid is suppressed in the mixed solution, and a composite dopant compound formed by bonding the organic compound and the Lewis acid in the thin film from which the organic solvent has evaporated dopes the organic semiconductor material.

8. The method of claim 7, wherein the bonding forms a Lewis pair formed by the cyano group (C≡N) of the organic compound and the Lewis acid.

9. The method of claim 1, wherein the organic semiconductor material contains an alkyl side chain in its molecular structure.

10. A doped organic semiconductor thin film comprising:
a composite dopant compound in which an organic compound having a resonance structure having at least one cyano group (C≡N) and a Lewis acid are combined; and
an organic semiconductor material doped with the composite dopant compound.

11. The doped organic semiconductor thin film of claim 10, wherein the combination of the organic compound and the Lewis acid forms a Lewis pair between the cyano group (C≡N) of the organic compound and the Lewis acid.

12. The doped organic semiconductor thin film of claim 11, wherein the thin film is formed using a composite doping solution containing the organic compound, the Lewis acid, and an organic solvent, and the combination of the organic compound and the Lewis acid is formed after the organic solvent evaporates while the above thin film is formed.

13. The doped organic semiconductor thin film of claim 12, wherein the organic solvent has a dielectric constant value of 16 to 50 at room temperature.

14. The doped organic semiconductor thin film of claim 13, wherein the organic solvent comprises at least one selected from acetone, acetonitrile (ACN), dimethylformamide (DMF), and combinations thereof.

15. The doped organic semiconductor thin film of claim 10, wherein the organic semiconductor material contains an alkyl side chain in its molecular structure.
